(19) United States
(12) Patent Application Publication
(10) Pub. No.: US 2013/0270546 A1
(43) Pub. Date: Oct. 17, 2013

(54) ACTIVE DEVICE AND FABRICATING METHOD THEREOF

(71) Applicants: Chih-Pang Chang, Taipei City (TW); Hsing-Hung Hsieh, Changhua County (TW)

(72) Inventors: Chih-Pang Chang, Taipei City (TW); Hsing-Hung Hsieh, Changhua County (TW)

(73) Assignee: AU OPTRONICS CORPORATION, Hsinchu (TW)

(21) Appl. No.: 13/531,600

(22) Filed: Jun. 25, 2012

(30) Foreign Application Priority Data
Apr. 13, 2012 (TW) 101113285

(51) Int. Cl. H01L 29/786; H01L 21/336

(52) U.S. Cl. 257/43; 438/151; 257/E29.273; 257/E21.411

(57) ABSTRACT

An active device and a fabricating method thereof are provided. The active device includes a buffer layer, a channel, a gate, a gate insulation layer, a source and a drain. The buffer layer is disposed on a substrate and has a positioning region. A thickness of a portion of the buffer layer in the positioning region is greater than a thickness of a portion of the buffer layer outside the positioning region. The channel is disposed on the buffer layer and in the positioning region. The gate is disposed above the channel. The gate insulation layer is disposed between the channel and the gate. The source and the drain are disposed above the channel and electrically connected to the channel.

### CROSS-REFERENCE TO RELATED APPLICATION

This application claims the priority benefit of Taiwan application serial no. 101113285, filed on Apr. 13, 2012. The entirety of the above-mentioned patent application is hereby incorporated by reference herein and made a part of this specification.

### BACKGROUND OF THE INVENTION

1. Field of the Invention

The present invention relates to an active device and a fabricating method thereof.

2. Description of Related Art

A thin film transistor liquid crystal display (TFT LCD) panel mainly consists of an active device array structure, a color filter array structure and a liquid crystal layer. The active device array structure includes multiple active devices arranged in array, i.e. an array of thin film transistors (TFTs), and a pixel electrode disposed in correspondence with each TFT. The TFT includes a gate, a channel, a drain and a source. The TFT serves as a switch element for a liquid crystal display unit.

An oxide semiconductor is a common material for fabricating the TFT. When the oxide semiconductor TFT is used as the switch element for the liquid crystal display unit, because the channel of the oxide semiconductor material has a high light transmittance, there has been an alignment difficulty in stacking other materials in subsequent processes. Although increasing the thickness of the channel of the oxide semiconductor material may decrease its light transmittance, it causes a threshold voltage shift of the channel. Therefore, when the oxide semiconductor TFT is used as the switch element, it is desired to achieve high alignment accuracy in the process without increasing the thickness of the oxide semiconductor.

### SUMMARY OF THE INVENTION

Accordingly, the present invention is directed to an active device having a buffer layer with a positioning region, and a channel disposed in the positioning region and a portion of the buffer layer in the positioning region can serve as a positioning mark used in the fabrication process of the active device.

The present invention is also directed to a method for fabricating an active device. The active device has a buffer layer with a positioning region. A channel disposed in the positioning region and a portion of the buffer layer in the positioning region can facilitate alignment in subsequent processes.

The present invention provides an active device including a buffer layer, a channel, a gate, a gate insulation layer, a source and a drain. The buffer layer is disposed on a substrate and has a positioning region. A thickness of a portion of the buffer layer in the positioning region is greater than a thickness of a portion of the buffer layer outside the positioning region. The channel is disposed on the buffer layer and in the positioning region. The gate is disposed above the channel. The gate insulation layer is disposed between the channel and the gate. The source and the drain are disposed above the channel and electrically connected with the channel.

In one embodiment, the thickness of the portion of the buffer layer in the positioning region is X1, the thickness of the portion of the buffer layer outside the positioning region is X2, the thickness of the channel is Y, and the result of subtracting X2 from the sum of X1 and Y is equal to or greater than 60 nanometers.

In one embodiment, the thickness of the channel is equal to or less than 70 nanometers.

In one embodiment, the material of the buffer layer is silicon oxide (SiOx), silicon nitride (SiNx), silicon nitride-oxide (SiON), silicon carbide (SiC), silicon carbonitride (SiCN) or aluminum oxide (AlO).

In one embodiment, the active device further includes a first insulation layer covering the gate and the gate insulation layer. The source and the drain are disposed on the first insulation layer, and the source and the drain pass through the first insulation layer and the gate insulation layer to be electrically connected with the channel.

In one embodiment, the material of the channel is an oxide semiconductor.

In one embodiment, the material of the channel includes indium-gallium-zinc oxide (IGZO), zinc oxide (ZnO), tin oxide (SnO), indium-zinc oxide (IZO), gallium-zinc oxide (GZO), zinc-tin oxide ZTO, indium-gallium oxide (IGO), indium-tin-zinc oxide (ITZO), or indium-tin oxide (ITO).

The present invention provides a method for fabricating an active device. In this method, a buffer layer is first formed on a substrate. A channel material layer is then formed on the buffer layer, and this channel material layer is patterned to form a channel later. The buffer layer has a positioning region, and a thickness of a portion of the buffer layer in the positioning region is greater than a thickness of a portion of the buffer layer outside the positioning region. The channel is disposed on the buffer layer and in the positioning region. After the channel and the buffer layer with two thicknesses, a gate insulation layer is then formed on the channel. A gate is then formed on the gate insulation layer, with the channel and the portion of the buffer layer below the channel being used as an alignment mark. Finally, a source and a drain are formed which are above the channel and electrically connected to the channel.

In one embodiment of the fabricating method of the active device, the step of forming the channel includes patterning the channel material layer to form the channel, and thinning the portion of the buffer layer that is not covered by the channel, such that the thickness of the portion of the buffer layer below the channel is greater than the thickness of the portion of the buffer layer that is not covered by the channel.

In one embodiment of the fabricating method of the active device, the method of forming the channel and thinning the portion of the buffer layer that is not covered by the channel include the following steps. An etch mask is formed on a region of the channel material layer where the channel is to be formed. The portion of the channel material layer that is not covered by the etch mask is etched to form the channel, and then the portion of the buffer layer that is not covered by the channel is etched. Finally, the etch mask is removed.

In one embodiment of the fabricating method of the active device, the step of forming the channel includes patterning the channel material layer and the buffer layer at one time to form the channel layer and the buffer layer having two thicknesses.

In one embodiment of the fabricating method of the active device, the method further includes, after the gate is formed and before the source and the drain are formed, forming a first gate insulation layer to cover the gate and the gate insulation layer, with the source and the drain passing through the first insulation layer and the gate insulation layer to be electrically connected with the channel.

In view of the foregoing, in the present active device and the fabricating method thereof, the thickness of the buffer layer below the channel is greater than the thickness of the rest part of the buffer layer. Therefore, the channel and the buffer layer below the channel can serve as an alignment mark used in the fabrication process.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1A to FIG. 1I are cross-sectional views illustrating a flow of a method for manufacturing an active device according to one embodiment of the present invention.

FIG. 2A to FIG. 2F are cross-sectional views illustrating the flow of the method of fabricating the channel and the buffer layer of FIG. 1C.

### DESCRIPTION OF THE EMBODIMENTS

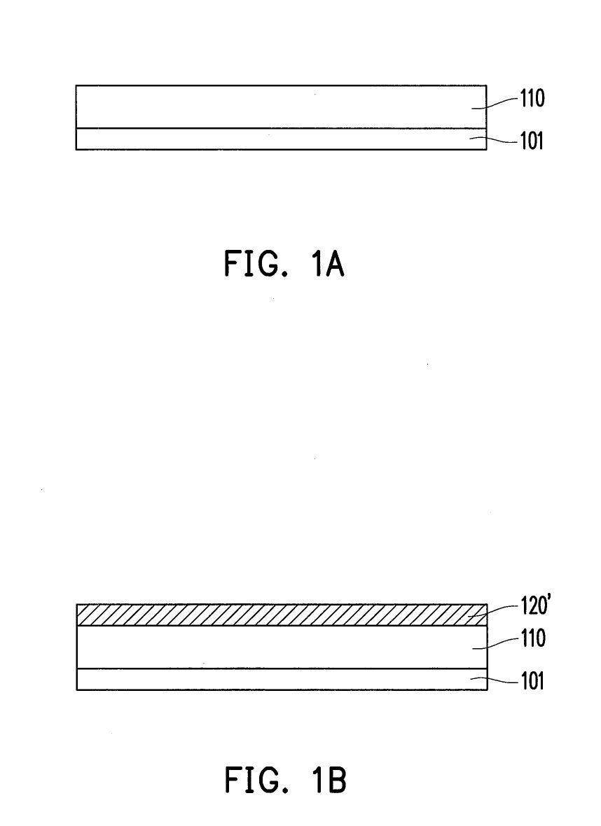

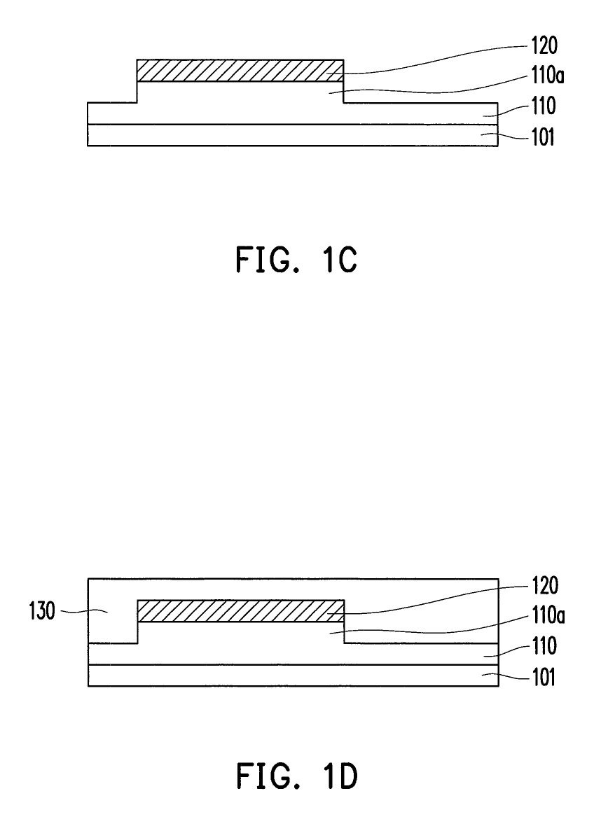

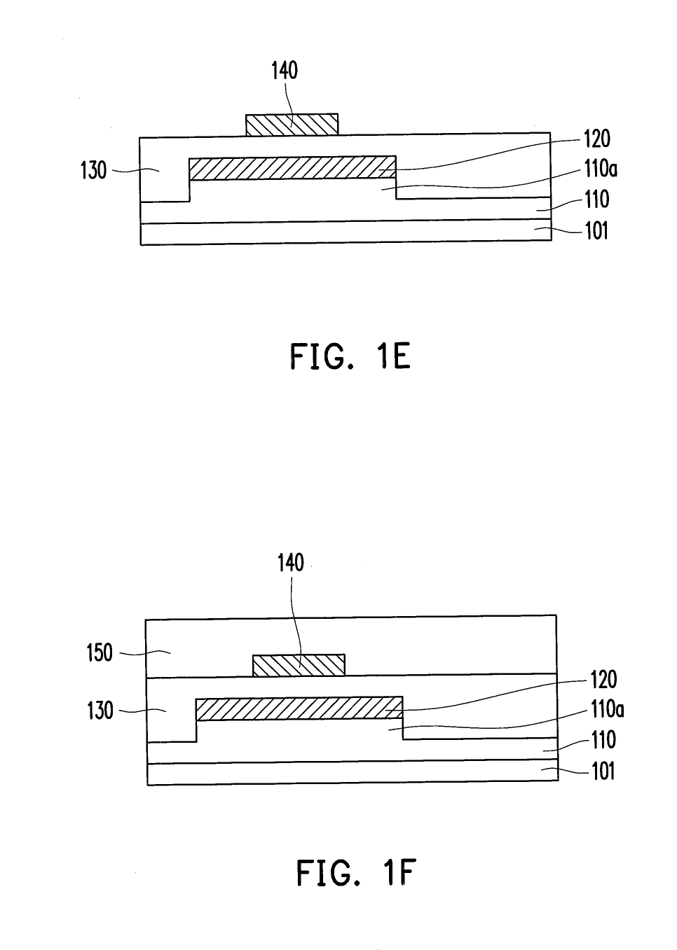

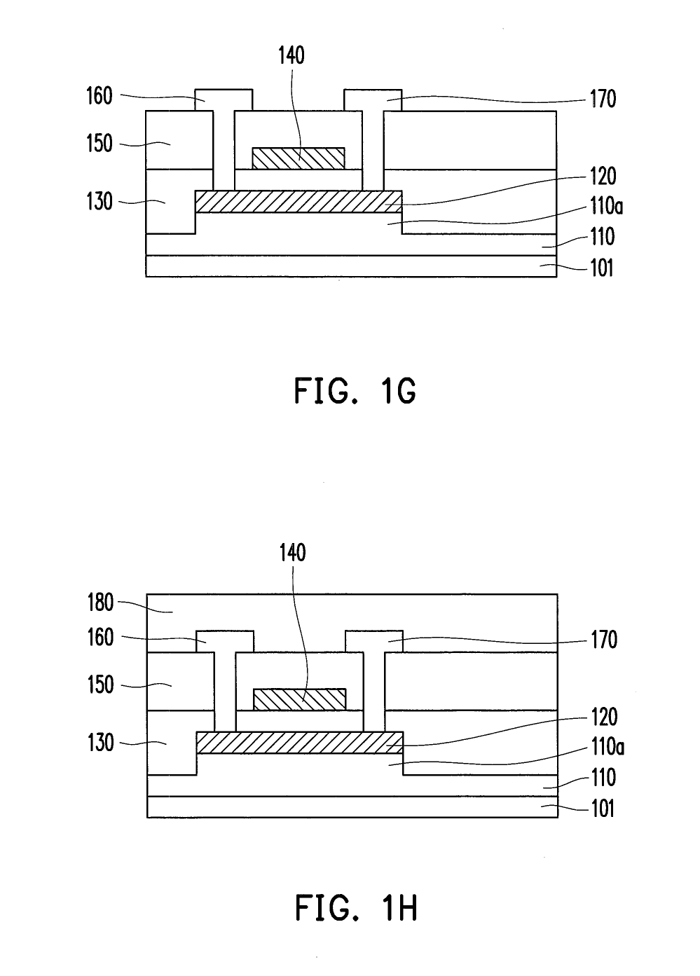

FIG. 1A to FIG. 1I are cross-sectional views illustrating a flow of a method for manufacturing an active device according to one embodiment of the present invention. Referring first to FIG. 1A, a substrate 101 is provided, which is, for example, a glass substrate or a plastic substrate. A buffer layer 110 is then formed on the substrate 101. Referring to FIG. 1B, a channel material layer 120′ is then formed on the buffer layer 110. The buffer layer 110 can prevent impurities in the substrate 101 from diffusing into the channel material layer 120′ which would contaminate the channel material layer 120′ or even further affect the electricity of the active device 100 when driven. In addition, since the buffer 110 covers the entire substrate 101, the buffer 110 can also suppress the degree of warp of the substrate 101.

Referring to FIG. 1C, the channel material layer 120′ may be patterned to form a channel 120 after the buffer layer 110 and the channel material layer 120′ are formed on the substrate 101. The buffer layer 110 includes a positioning region 110a, and a thickness of the buffer layer 110 in the positioning region 110a is greater than a thickness of the buffer layer 110 outside the positioning region 110a. The channel 120 formed from the channel material layer 120′ is disposed on the buffer layer 110 and located in the positioning region 110a.

Referring to FIG. 1D, after the channel 120 and the buffer layer 110 with two thicknesses are formed, a gate insulation layer 130 is formed over the channel 120. The gate insulation layer 130 has insulation result and can isolate the channel 120 from a gate 140 to be formed later (shown in FIG. 1E). The method for forming the gate insulation layer 130 may be, but not limited to, chemical vapor deposition (CVD). The gate insulation layer 130 may also be formed using other methods, such as, screen printing, coating, ink-jetting, energy source processing, or the like. The present invention has no limits as to the formation of the gate insulation layer 130.

Referring to FIG. 1E, a gate 140 is formed on the gate insulation layer 130. In comparison with the buffer layer 110 outside the positioning region 110a, the stacked channel 120 in the positioning region 110a and the buffer layer 110 in the positioning region 110a have a relatively greater thickness and therefore has a different light transmittance than that of the buffer layer 110 outside the positioning region 110a. In forming the gate 140 on the gate insulation layer 130, the channel 120 and the portion of the buffer layer 110 below the channel 120 may serve as an alignment mark by taking advantage of this difference in light transmittance. In other words, in forming the gate 140 in the subsequent process, alignment of the gate 140 can be achieved without using additional alignment pattern.

Referring to FIG. 1F, after the gate 140 is formed, a first insulation layer 150 is then formed. The first insulation layer 150 covers both the gate 140 and the gate insulation layer 130. Referring again to FIG. 1G, a source 160 and a drain 170 are formed above the channel 120 and are electrically connected with the channel 120. The source 160 and the drain 170 are spaced a distance and pass through the first insulation layer 150 and the gate insulation layer 130 to be electrically connected with the channel 120 therebelow. The active device of this embodiment is thus generally accomplished. Discussed below are some other optional steps.

Referring to FIG. 1H, after the source 160 and the drain 170 are formed, a second insulation layer 180 is then formed to cover the source 160 and the drain 170. Referring to FIG. 1I, a pixel electrode 190 is formed on the second insulation layer 180, and the pixel electrode 190 and the drain 170 are electrically connected.

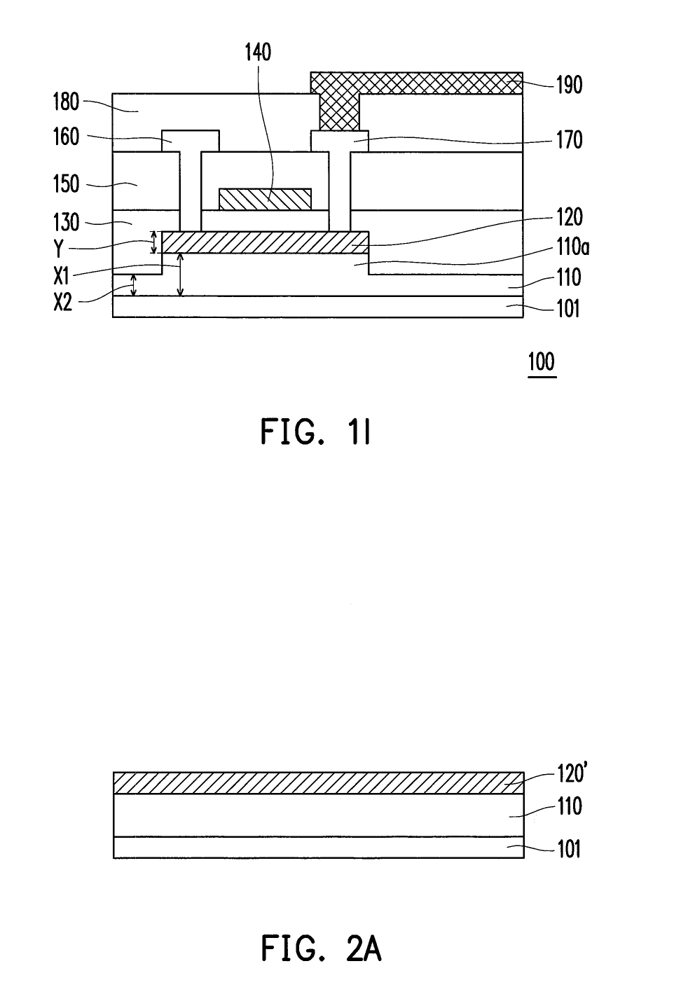

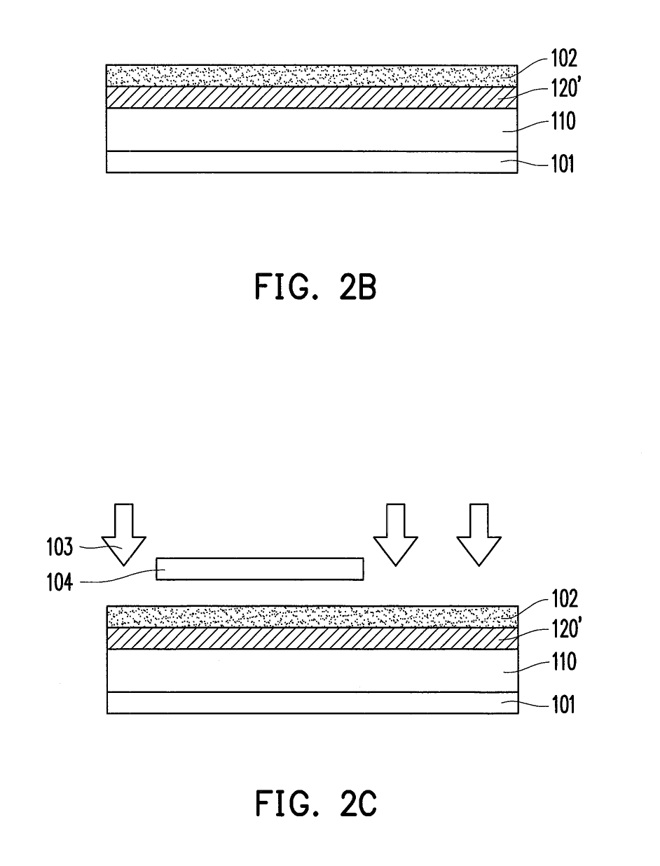

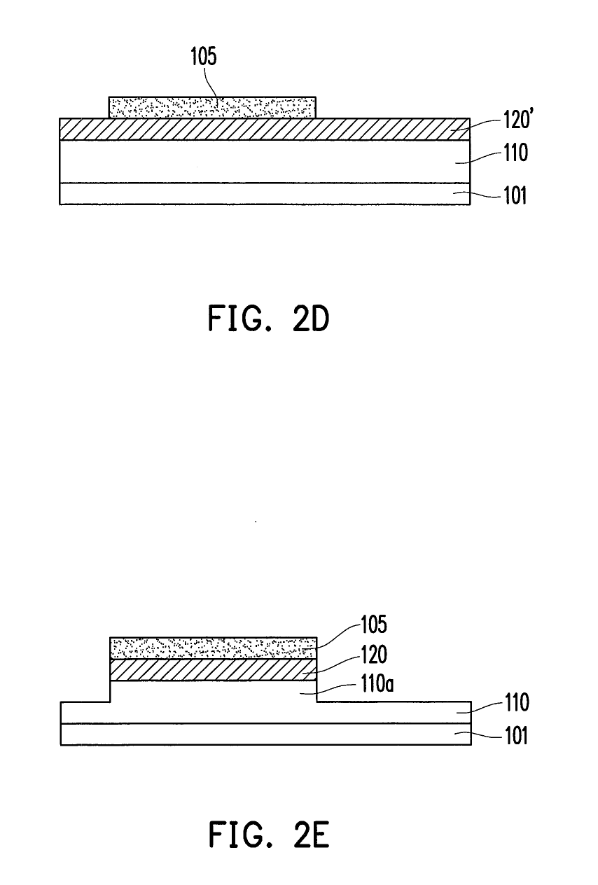

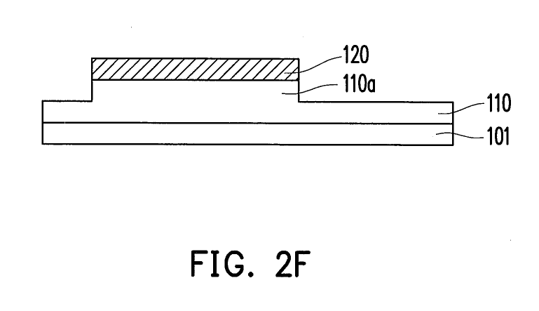

FIG. 2A to FIG. 2F are cross-sectional views illustrating the flow of the method of fabricating the channel and the buffer layer of FIG. 1C. Referring to FIG. 2A and FIG. 2B, after obtaining the semi-finished product shown in FIG. 1B, a photoresist material layer 102 may be coated on the channel material layer 120′ using a coating method such as spin coating or slot die coating, such that the photoresist layer 102 covers the channel material layer 120′.

Referring to FIG. 2C, the photoresist layer 102 is exposed to an ultraviolet light 103 through a photo mask 104. The design of the pattern (distribution of the shielding region and the transparent region) of the photo mask 104 may vary according to photosensitivity of the photoresist layer 102. For example, the pattern design of the photo mask 104 for the photoresist layer 102 having a positive photosensitivity is inverted with respect to the mask pattern design for the photoresist layer 102 having a negative photosensitivity.

Referring to FIG. 2C and FIG. 2D, a development step is executed using a developing solution such that part of the photoresist layer 102 is removed. In the present embodiment, the photoresist material used has a negative photosensitivity. Therefore, the exposed part of the photoresist material layer 102 is dissolved in the developing solution so as to be removed and the rest part remains on the channel material layer 120′ to form an etch mask 105 in the region where the channel 120 is to be formed.

Referring to FIG. 2E, after the etch mask 105 is formed, an etch operation may be performed on the underlying channel material layer 120′ and the buffer layer 110 through the etch mask 105. Notably, etch can be performed in two manners. The first manner is layered etch. The part of the channel material layer 120′ that is not covered by the etch mask 105 is etched to form the channel 120. After the channel 120 is formed, a second etch is performed to remove the part of the buffer layer 110 that is not covered by the etch mask 105. In the second manner, the channel material layer 120′ and the buffer layer 110 are patterned at one time to form the channel 120 and the buffer layer 110 having two thicknesses. At the step shown in FIG. 2E, the channel material layer 120′ is etched to form the channel, and the buffer layer 110 that originally had a uniform thickness is etched to have two portions with different thicknesses. The thickness of the buffer layer 110 in the positioning region 110a is greater than the thickness of the buffer layer 110 outside the positioning region 110a.

Referring to FIG. 2F, finally, the etch mask 105 shown in FIG. 2E is removed, and a structure on the substrate 101 that includes the buffer layer 110 with the positioning region 110a and the channel 120 is thus obtained. This structure may serve as the alignment mark for the formation of the gate 140 in a subsequent process.

In addition, in FIG. 1E, FIG. 1G and FIG. 1I, the gate 140, source 160, drain 170 and pixel electrode 190 are likewise formed using a photo process similar to that illustrated in FIG. 2A to FIG. 2F. The only difference is that the pattern of the photo mask 104 used in FIG. 2C needs to change according to the desired shape of the gate 140, source 160, drain 170 and pixel electrode 190. Therefore, further explanation of the photo process is not repeated herein.

FIG. 1I illustrates an active device according to one embodiment of the present invention. Referring to FIG. 1I, the active device 100 includes a buffer layer 110, a channel 120, a gate 140, a gate insulation layer 130, a source 160 and a drain 170. The buffer layer 110 is disposed on a substrate 101. The buffer layer 110 includes a positioning region 110a. A thickness of a portion of the buffer layer 110 in the positioning region 110a is greater than a thickness of a portion of the buffer layer 110 outside the positioning region 110a. The channel 120 is disposed on the buffer layer 110 and in the positioning region 110a. The gate 140 is disposed above the channel 120. A gate insulation layer 130 is disposed between the channel 120 and the gate 140. The source 160 and the drain 170 are disposed above the channel 120 and electrically connected with the channel 120.

In the active device 100 of the present embodiment, the buffer layer 110 and the channel 120 in the positioning region 110a can collectively serve as a positioning mark. Therefore, even if the thickness of the channel 120 is controlled to be less than 70 nanometers, it would not cause the alignment difficulty in subsequent processes due to the over-thin thickness. In addition, when the material of the channel 120 is an oxide semiconductor, controlling the channel 120 to have a suitable thickness can also avoid the threshold voltage shift issue of the channel 120.

The thickness of the portion of the buffer layer 110 in the positioning region 110a is X1, the thickness of the portion of the buffer layer 110 outside the positioning region 110a is X2, and the thickness of the channel 120 is Y. The result of subtracting X2 from the sum of X1 and Y is equal to or greater than 60 nanometers. In other words, the sum of the thickness of the portion of the buffer 110 in the positioning region 110a and the thickness of the channel 120 must be greater than the thickness of the portion of the buffer layer 110 outside the positioning region 110a, such that the light transmittance of the positioning region 110a and the light transmittance of the portion outside the positioning region 110a have a sufficient difference for the fabrication equipment to identify to achieve the positioning result. The thickness of the channel 120 can be less than 70 nanometers. The material of the buffer layer 110 is an insulation material, for example, a metal oxide material such as, silicon oxide (SiOx), silicon nitride (SiNx), silicon nitride-oxide (SiON), silicon carbide (SiC), silicon carbonitride (SiCN) or aluminum oxide (AlO). The material of the channel 120 may be an oxide semiconductor, such as, indium-gallium-zinc oxide (IGZO), zinc oxide (ZnO), tin oxide (SnO), indium-zinc oxide (IZO), gallium-zinc oxide (GZO), zinc-tin oxide (ZTO), indium-gallium oxide (IGO), indium-tin-zinc oxide (ITZO), or indium-tin oxide (ITO).

As shown in FIG. 1I, the active device 100 of the present embodiment further includes a first insulation layer 150. The first insulation layer 150 covers the gate electrode 140 and the gate insulation layer 130. The source 160 and the drain 170 are disposed on the first insulation layer 150, and the source 160 and the drain 170 pass through the first insulation layer 150 and the gate insulation layer 130 to be electrically connected with the channel 120.

The material of the gate 140, source 160 and drain 170 may be a metal such as aluminum (Al), molybdenum (Mo), chromium (Cr), tantalum (Ta), titanium (Ti), gold (Au) or silver (Ag) or any alloy thereof, an alloy such as Al—Nd, APC, or a conductive metal oxide such as tin oxide (SnO), zinc oxide (ZnO), indium oxide, indium-tin oxide (ITO) or indium-zinc oxide (IZO). It is noted, however, the present invention is not intended to limit the material of the gate 140, source 160 and drain 170 to any particular material.

Referring to 1I, the active device 100 of the present embodiment may further include a second insulation layer 180 and a pixel electrode 190. The material of the pixel electrode 190 may be, for example, indium-tin oxide (ITO) or aluminum zinc oxide (AZO). It is noted, however, that the present invention is not intended to limit the material of the pixel electrode 190 to any particular material.

In summary, in the active device of the present invention, the stacked structure itself can serve as a positioning mark for use in the fabricating process of the active device. This positioning mark consists of the buffer layer and the channel in the positioning region. The thickness of the stacked buffer layer and channel in the region is greater than the thickness of the buffer layer outside the positioning region. Therefore, the stacked buffer layer and channel in the positioning region and the buffer layer outside the positioning region have different light transmittance. The stacked structure may serve as the positioning mark for use in subsequent processes by taking advantage of the difference in light transmittance.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An active device, comprising:
a buffer layer disposed on a substrate and having a positioning region, wherein a thickness of a portion of the buffer layer in the positioning region is greater than a thickness of a portion of the buffer layer outside the positioning region;
a channel disposed on the buffer layer and in the positioning region;
a gate disposed above the channel;
a gate insulation layer disposed between the channel and the gate; and
a source and a drain disposed above the channel and electrically connected with the channel.

2. The active device according to claim 1, wherein the thickness of the portion of the buffer layer in the positioning region is X1, the thickness of the portion of the buffer layer outside the positioning region is X2, the thickness of the channel is Y, and the result of subtracting X2 from the sum of X1 and Y is equal to or greater than 60 nanometers.

3. The active device according to claim 1, wherein the thickness of the channel is equal to or less than 70 nanometers.

4. The active device according to claim 1, wherein the material of the buffer layer is silicon oxide, silicon nitride, silicon nitride-oxide, silicon carbide, silicon carbonitride or aluminum oxide.

5. The active device according to claim 1, further comprising a first insulation layer covering the gate and the gate insulation layer, wherein the source and the drain are disposed on the first insulation layer, and the source and the drain pass through the first insulation layer and the gate insulation layer to be electrically connected with the channel.

6. The active device according to claim 1, wherein the material of the channel is an oxide semiconductor.

7. The active device according to claim 1, wherein the material of the channel comprises indium-gallium-zinc oxide, zinc oxide, tin oxide, indium-zinc oxide, gallium-zinc oxide, zinc-tin oxide, indium-gallium oxide, indium-tin-zinc oxide, or indium-tin oxide.

8. A method for fabricating an active device, comprising:
forming a buffer layer on a substrate;
forming a channel material layer on the buffer layer;
forming a channel, wherein the buffer layer having a positioning region, a thickness of a portion of the buffer layer in the positioning region is greater than a thickness of a portion of the buffer layer outside the positioning region, and the channel is disposed on the buffer layer and in the positioning region;
forming a gate insulation layer on the channel;
forming a gate on the gate insulation layer, with the channel and the portion of the buffer layer below the channel being used as an alignment mark; and
forming a source and a drain that are above the channel and electrically connected to the channel.

9. The method for fabricating the active device according to claim 8, wherein the step of forming the channel comprises:
patterning the channel material layer to form the channel;
thinning the portion of the buffer layer that is not covered by the channel, such that the thickness of the portion of the buffer layer below the channel is greater than the thickness of the portion of the buffer layer that is not covered by the channel.

10. The method for fabricating the active device according to claim 9, wherein the method of forming the channel and thinning the portion of the buffer layer that is not covered by the channel comprises:
forming an etch mask on a region of the channel material layer where the channel is to be formed;
etching the portion of the channel material layer that is not covered by the etch mask to form the channel, and continuing to etch the portion of the buffer layer that is not covered by the channel; and
removing the etch mask.

11. The method for fabricating the active device according to claim 8, wherein the step of forming the channel comprises:
patterning the channel material layer and the buffer layer at one time to form the channel layer and the buffer layer having two thicknesses.

12. The method for fabricating the active device according to claim 8, further comprising, after the gate is formed and before the source and the drain are formed, forming a first gate insulation layer to cover the gate and the gate insulation layer, with the source and the drain passing through the first insulation layer and the gate insulation layer to be connected with the channel.
